(19) United States
(12) Patent Application Publication
(10) Pub. No.: US 2009/0295965 A1
(43) Pub. Date: Dec. 3, 2009

(54) METHOD AND CIRCUIT FOR DRIVING ACTIVE PIXELS IN A CMOS IMAGER DEVICE

(75) Inventors: Desmond Yu Hin Cheung, Irvine, CA (US); Amit Mittra, Irvine, CA (US); Chi-Shao Lin, Hsinchu (TW)

Correspondence Address: GENE I. SU, 17F-1, No. 151, SEC. 4, XINYI ROAD, TAIPEI, TW

(73) Assignee: HIMAX IMAGING, INC., Grand Cayman (KY)

(21) Appl. No.: 12/129,900

(22) Filed: May 30, 2008

(51) Int. Cl. H04N 5/335; H01L 27/146

(52) U.S. Cl. 348/308; 257/292; 348/E05.091; 257/E27.133

(57) ABSTRACT

One embodiment of the present invention describes a pixel circuit that comprises at least one photodiode, a first transistor coupled between the photodiode and a floating diffusion node, a second transistor coupled between the floating diffusion node and a modifiable driving voltage signal, and a third transistor having a gate coupled to the floating diffusion node, a source coupled to a signal output, and a drain coupled to a constant voltage. Another embodiment of the present invention provides a method for driving the pixel circuit, which comprises resetting the photodiode and the floating diffusion node, exposing the photodiode to light to accumulate charges, selecting the pixel circuit by switching the driving voltage signal from a first voltage level to a second voltage level, retrieving a reference voltage from the selected pixel circuit, and retrieving an image signal from the selected pixel circuit corresponding to the accumulated charges.

### BACKGROUND OF THE INVENTION

1. Field of the Invention

The present invention generally relates to complementary metal-oxide semiconductor (CMOS) imager devices, and more particularly to a method and circuit for driving active pixels in a CMOS imager device.

2. Description of the Related Art

Unless otherwise indicated herein, the approaches described in this section are not prior art to the claims in this application and are not admitted to be prior art by inclusion in this section.

A CMOS imager device is typically formed of an array of active pixels that are operable to capture the image of an object in an electrical signal form. Each active pixel has a pixel circuit that comprises a photodiode for converting light into an electrical signal representative of an image signal, and a readout circuit adapted to amplify and retrieve the electrical signal from the active pixel. Ideally, the active pixel should have a large photodiode surface area that is unobstructed to capture incident light in an efficient manner. However, for products that require small form factors, such as small digital cameras, the pixel size is restricted to be as small as possible.

A practical approach to reduce the pixel size is to reduce the size of the readout circuit and to overlap parts of the physical structures and metal interconnects of the readout circuit over the photodiode surface area. However, such an approach results in an actual light sensitive area of the photodiode that is smaller than the surface of the photodiode. In other words, the size of the readout circuit and its structure significantly influences the amount of light that reaches the photodiode.

Some typical CMOS pixel circuit configurations include 4-transistor and 3-transistor configurations. In the 4-transistor configuration, one active pixel circuit comprises one photodiode for collecting integrated charges generated in response to incident light, and four transistors through which the integrated charge is transferred to read out an image signal. In the 3-transistor configuration, the active pixel circuit comprises one photodiode and three transistors through which the integrated charge is transferred to read out the image signal. Compared to the 4-transistor configuration, the 3-transistor configuration provides a higher pixel fill factor. However, to replace the function of the extra transistor of the 4-transistor configuration, the 3-transistor pixel circuit requires a driving method in which concurrent charging of a selected row of active pixels and discharging of unselected rows of active pixels are required to enable signal readout from the selected row of active pixels. As a result of the frequent charging and discharging of the array of active pixels during operation, more power is consumed, and undesirable noises may be generated due to power line coupling.

What is needed in the art is thus a method and circuit that can drive CMOS active pixels in a more efficient manner and address at least the problems set forth above.

### SUMMARY OF THE INVENTION

The present application describes a method and circuit for driving active pixels in a CMOS imager device. Specifically, one embodiment of the present invention sets forth a pixel circuit that comprises at least one photodiode, a first transistor coupled between the photodiode and a floating diffusion node, a second transistor coupled between the floating diffusion node and a modifiable driving voltage source, and a third transistor having a gate coupled to the floating diffusion node, a source coupled to a signal output, and a drain coupled to a constant voltage.

In another embodiment, an imager device is disclosed. The imager device comprises an array of active pixels arranged in rows and columns, a row driver circuit configured to provide control signals to each row of active pixels, and a signal output circuit configured to receive analog signals issued by each column of active pixels, wherein each active pixel in a same row has a pixel circuit that comprises at least one photodiode, a first transistor coupled between the photodiode and a floating diffusion node, a second transistor coupled between the floating diffusion node and a driving voltage signal commonly coupled to all active pixels in the row, and a third transistor having a gate coupled to the floating diffusion node, a source coupled to a signal output, and a drain coupled to a constant voltage.

In still another embodiment, a method for driving the pixel circuit is disclosed. The method comprises resetting the photodiode and the floating diffusion node, exposing the photodiode to light to accumulate charges, selecting the pixel circuit by switching the driving voltage signal from a first voltage level to a second voltage level, retrieving a reference voltage from the selected pixel circuit, and retrieving an image signal from the selected pixel circuit corresponding to the accumulated charges.

At least one advantage of the present invention disclosed herein is the ability to provide a pixel circuit that has a reduced number of transistors and can be selected and unselected for signal readout by simply modifying a driving voltage to which the pixel circuit is coupled. As a result, less power is consumed during operation and undesirable noises induced by power line coupling can be reduced.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the drawings. It is to be noted, however, that the drawings illustrate only typical embodiments of this invention and are therefore not to be considered limiting of its scope, for the invention may admit to other equally effective embodiments.

FIG. 1 is a circuit diagram of a pixel circuit for a CMOS imager device according to an embodiment of the present invention;

FIG. 2A is a flowchart of method steps for driving a pixel circuit according to an embodiment of the present invention;

FIG. 2B is a timing diagram illustrating an implementation of the method steps shown in FIG. 2A for driving the pixel circuit of FIG. 1;

FIG. 3 is a circuit diagram of a pixel circuit for a CMOS imager device according to another embodiment of the present invention;

FIG. 4A is a flowchart of method steps for driving a pixel circuit according to another embodiment of the present invention;

FIG. 4B is a timing diagram illustrating an implementation of the method steps shown in FIG. 4A for driving the pixel circuit of FIG. 3; and

FIG. 5 is a conceptual diagram of a CMOS imager device according to an embodiment of the present invention.

### DETAILED DESCRIPTION

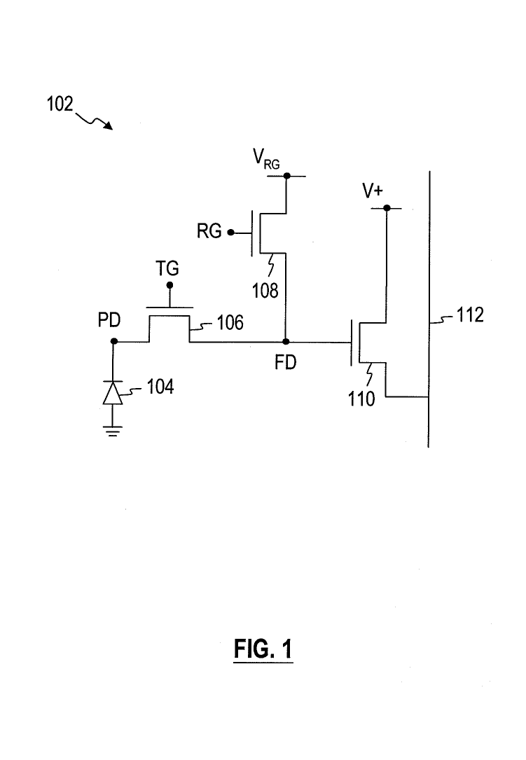

FIG. 1 is a circuit diagram of a pixel circuit 102 according to an embodiment of the present invention. The pixel circuit 102 comprises a photodiode 104 and three transistors, including a transfer transistor 106, a reset transistor 108, and a source follower transistor 110. Any of the transistors 106, 108, and 110 may be implemented as a metal-oxide-semiconductor field-effect transistor (MOSFET). The transfer transistor 106 has its source coupled to a photodiode node PD and its drain coupled to a floating diffusion node FD configured to receive charge accumulation transferred via the transfer transistor 106. The reset transistor 108 is coupled between the floating diffusion node FD and a driving voltage line V_{RG}. The reset transistor 108 is operable to reset the floating diffusion node FD and the photodiode 104, and control a gate voltage of the source follower transistor 110 to selectively switch the source follower transistor 110 between an ON state and an OFF state. The source follower transistor 110 has a gate coupled to the floating diffusion node FD, a drain coupled to a constant voltage V+, and a source coupled to a signal output column 112. Under control of the reset transistor 108, the source follower transistor 110 is operable to selectively enable or disable the pixel circuit 102 for retrieving electrical signals corresponding to charges stored in the floating diffusion node FD.

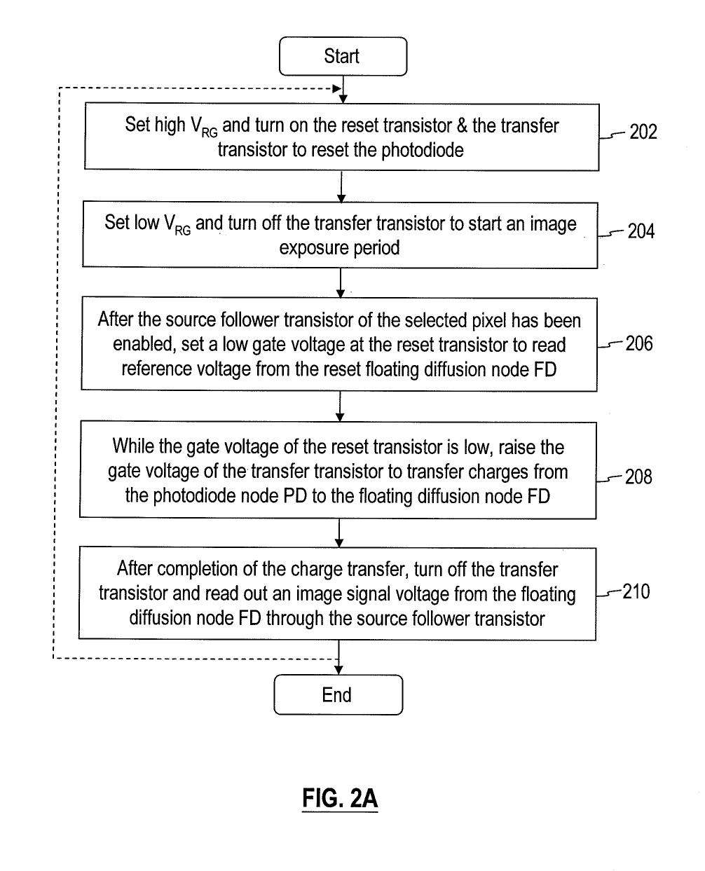

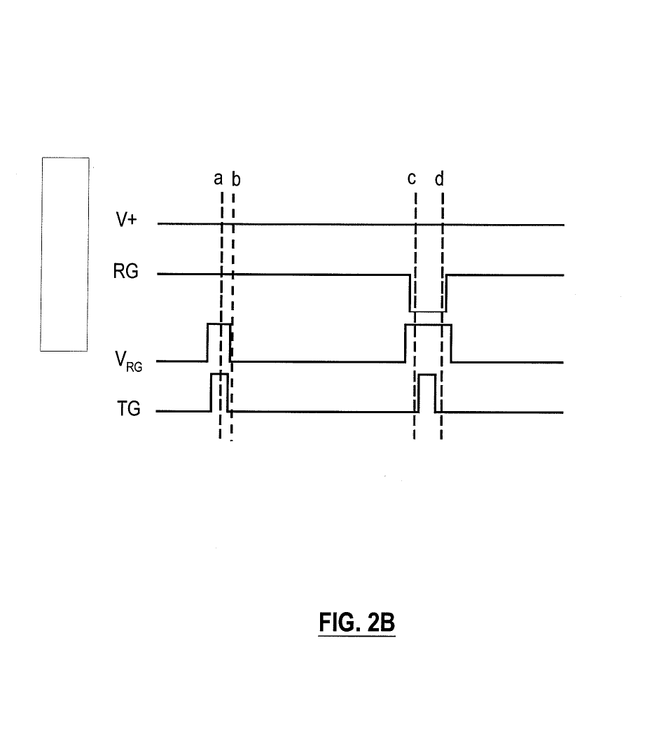

In conjunction with FIG. 1, FIG. 2A is a flowchart of method steps for operating the pixel circuit 102 according to an embodiment of the present invention. Initially, in step 202, a reset operation is performed during which the driving voltage line V_{RG} is set to a high voltage level and the reset transistor 108 and the transfer transistor 106 are turned on to reset the photodiode 104 and the floating diffusion node FD. Subsequently, in step 204, the driving voltage line V_{RG} is set to a low voltage level whereas the transfer transistor 106 is turned off to start an image exposure period for capturing image light. During image exposure, light striking on the photodiode 104 causes the integration of a photocurrent, and consequently electrical charges are accumulated at the photodiode node PD. Steps 206-210 are then performed to selectively enable signal readout from the pixel circuit 102 to the signal output column 112.

Specifically, in step 206, after the floating diffusion node FD is turned high and the source follower transistor 110 enabled by setting the driving voltage line V_{RG} and the gate voltage RG of the reset transistor 108 to high voltage levels, the gate voltage RG of the reset transistor 108 is then turned low to read out a reference voltage from the reset floating diffusion node FD to the signal output column 112. In step 208, while the gate voltage RG of the reset transistor 108 is low, the gate voltage TG of the transfer transistor 104 is set to a high voltage level to turn on the transfer transistor 104 and transfer the accumulated charges from the photodiode node PD to the floating diffusion node FD. In following step 210, after the charge transfer has been completed and the transfer transistor 104 turned off, an image signal voltage corresponding to the charges received at the floating diffusion node FD can then be read out at the signal output column 112 via the source follower transistor 110 in the ON state. The difference between the reference voltage and the image signal voltage retrieved at the signal output column 112 corresponds to the light signal sensed by the photodiode 104. After the image signal readout operation is completed, steps 202-210 may be repeated to capture and retrieve a next image signal.

FIG. 2B is a timing diagram illustrating an implementation of the method steps described in FIG. 2A for operating the pixel circuit 102. At time a, the photodiode 104 has been reset according to step 202. After step 204 is performed by setting the driving voltage line V_{RG} to a low voltage level and turning off the transfer transistor 106, an image exposure period of the reset pixel circuit 102 then starts at time b. At time c, after the driving voltage line V_{RG} and the gate voltage RG of the reset transistor 108 have been set high to enable the source follower transistor 110, the gate voltage RG of the reset transistor 108 is then turned low in accordance with step 206 to read the reference voltage from the floating diffusion node FD. Finally, at time d, the image signal voltage is read out from the floating diffusion node FD after steps 208 and 210 are performed.

Compared to a conventional 4-transistors pixel circuit, some advantages of the pixel circuit 102 described above include, without limitation, a reduced number of transistors, reduced power consumption, and reduced noises. Particularly, the pixel circuit 102 has only three transistors, which improves the fill factor. Also, the pixel circuit 102 can be selected and unselected for signal readout by simply modifying the single driving voltage line V_{RG} to which it is coupled. As a result, less power is consumed during operation, and power line coupling noises are reduced.

It is worth noting that while the above pixel driving method has been described with respect to a single photodiode pixel embodiment, the same driving method may also be advantageously applied for driving multiple pixels coupled in one common pixel circuit.

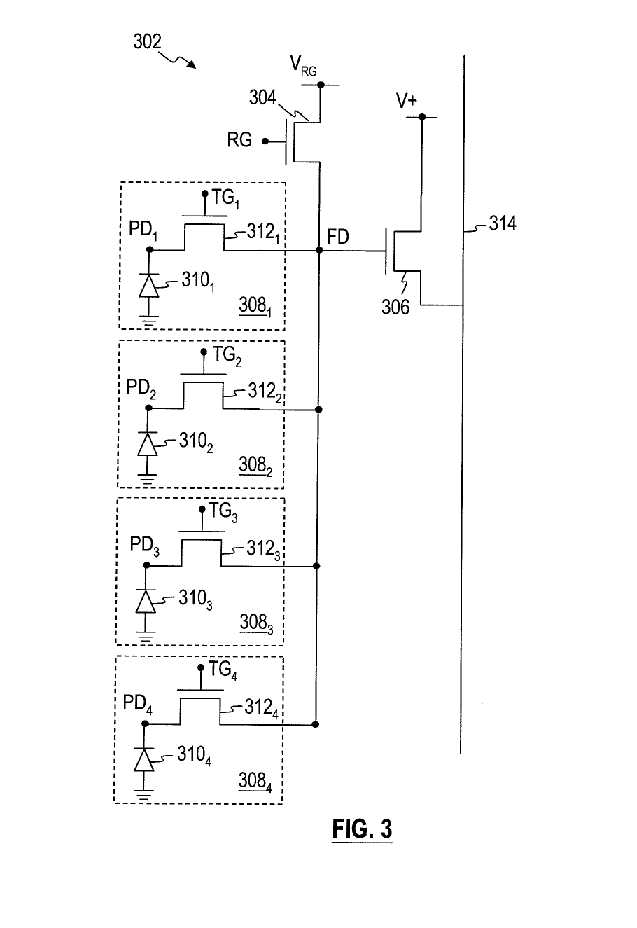

FIG. 3 is a circuit diagram illustrating a four-way-shared pixel circuit 302 according to an embodiment of the present invention. The pixel circuit 302 comprises a reset transistor 304 and a source follower transistor 306 that are coupled to four pixel blocks 308₁, 308₂, 308₃ and 308₄. Each pixel block 308ᵢ comprises a photodiode 310ᵢ and a corresponding transfer transistor 312ᵢ, wherein i is an index of the pixel block ranging from 1 to 4. Each transfer transistor 312ᵢ has a source connected to a photodiode node PDᵢ associated with each photodiode 310ᵢ, and a drain connected to a common floating diffusion node FD. The reset transistor 304 is coupled between the floating diffusion node FD and a driving voltage line V_{RG}. The reset transistor 304 is operable to reset the each photodiode 310ᵢ, and apply a control voltage to a gate of the source follower transistor 306 to selectively switch the source follower transistor 306 between an ON state and an OFF state. The source follower transistor 306 has a gate coupled to the floating diffusion node FD, a drain coupled to a constant voltage V+, and a source to a signal output column 314. Under control of the reset transistor 304, the source follower transistor 306 is operable to selectively enable/disable signal readout from each of the pixel blocks 308₁, 308₂, 308₃ and 308₄.

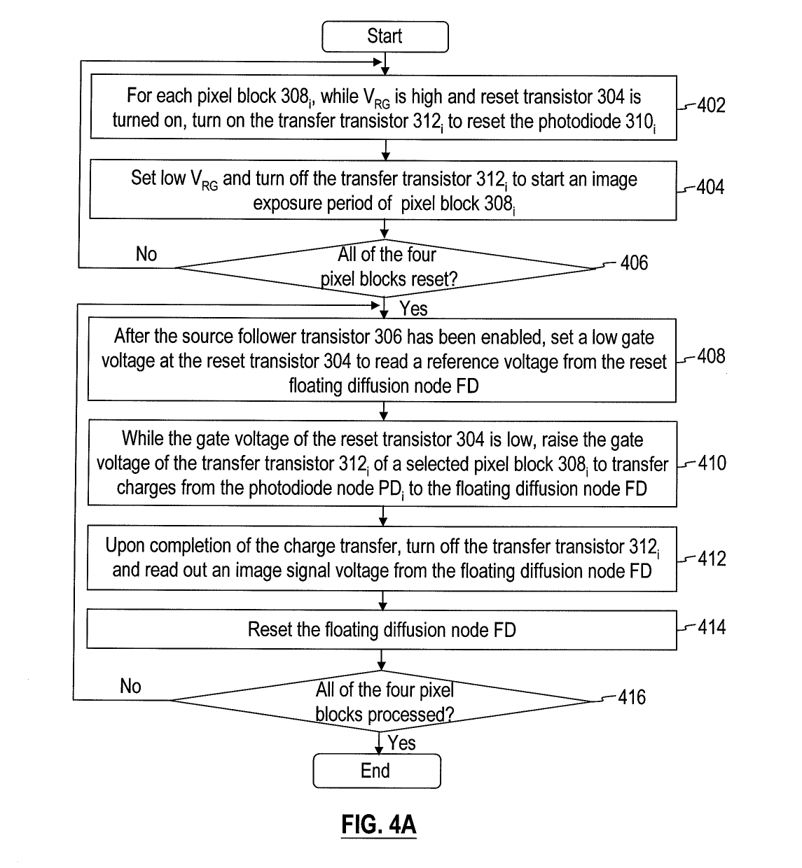

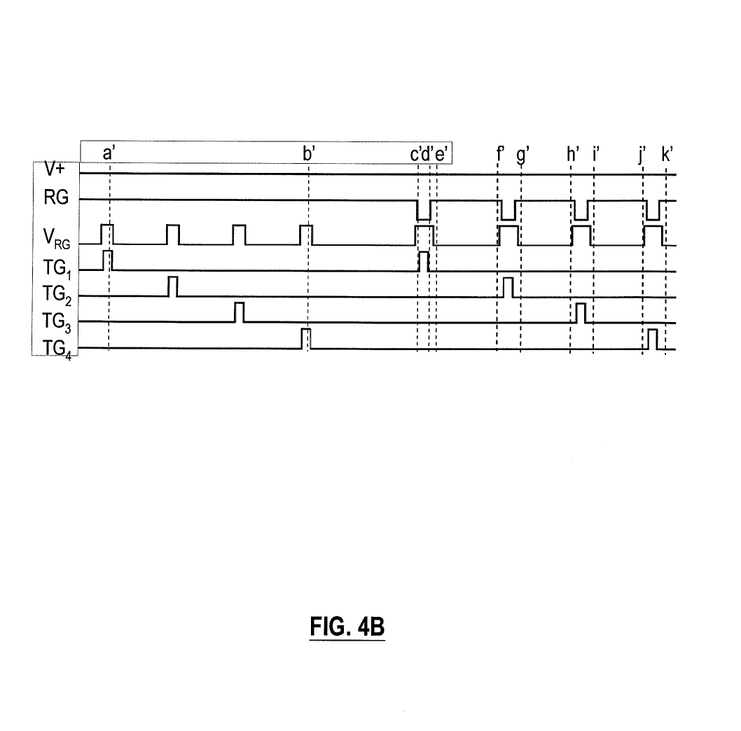

In conjunction with FIG. 3, FIG. 4A is a flowchart of method steps for operating the pixel circuit 302 according to an embodiment of the present invention. Initially, a reset operation is performed to reset the photodiode 310ᵢ of each pixel block 308ᵢ in a sequential manner. Thus in initial step 402, for each selected pixel block 308ᵢ, while the driving voltage line V_{RG} is set to a high voltage level and the reset transistor 304 is turned on by setting a high gate voltage RG, the transfer transistor 312ᵢ of the selected pixel block 308ᵢ is switched on by raising its gate voltage TGᵢ to reset the corresponding photodiode 310ᵢ. In step 404, the driving voltage line V_{RG} is then set to a low level, and the transfer transistors 312ᵢ is turned off by lowering its gate voltage TGᵢ to start an image exposure period of the pixel block 308ᵢ. Light striking on the photodiode 310ᵢ of the pixel block 308ᵢ during exposure causes the integration of a photocurrent, and consequently electric charges are accumulated at each corresponding photodiode node PDᵢ. After one pixel block has been reset, subsequent step 406 determines whether all the pixel blocks of the pixel circuit 302 have been reset. If it is not the case, steps 402 and 404 are repeated for each successive pixel block 308ᵢ until the photodiodes of all pixel blocks are reset.

After image exposure has been initiated for all the pixel blocks, steps 408-414 are performed to selectively retrieve image signals from each pixel block 308ᵢ in a sequential manner. More specifically, in step 408, after the floating node FD has been turned high and the source follower transistor 306 enabled by setting the driving voltage line V_{RG} and the gate voltage RG of the reset transistor 304 to high voltage levels, the gate voltage RG of the reset transistor 304 is then turned low to read out a reference voltage from the reset floating diffusion node FD to the signal output column 314. While the gate voltage RG of the reset transistor 304 is low, the transfer transistor 312ᵢ of a selected pixel block 308ᵢ is then turned on in step 410 by raising its gate voltage TGᵢ to transfer the accumulated charges from the photodiode node PDᵢ to the floating diffusion node FD. In step 412, after completion of the charge transfer from the selected pixel block 308ᵢ to the floating diffusion node FD, the transfer transistor 312ᵢ is then turned off by setting a low gate voltage TGᵢ and consequently the image signal voltage is retrieved at the signal output column 314. In step 414, the gate voltage RG of the reset transistor 304 is then turned high and V_{RG} turned low to reset the floating diffusion node FD. After the floating diffusion node FD is reset, subsequent step 416 determines whether all the pixel blocks have been processed to retrieve image signals. If it is not the case, steps 408-414 are repeated until all pixel blocks are processed. Once image signal readout is completed for all the pixel blocks, steps 402-414 may be repeated to capture next image signals.

FIG. 4B is a timing diagram illustrating an implementation of the method steps described in FIG. 4A for operating the pixel circuit 302 of FIG. 3. Between time a′ and b′, the photodiodes 310₁, 310₂, 310₃, 310₄ are reset in a sequential manner by repeatedly performing steps 402 and 404. At time c′, after the driving voltage line V_{RG} and the gate voltage RG of the reset transistor 304 have been set high to enable the source follower transistor 306, the gate voltage RG of the reset transistor 108 is then turned low as set forth in step 408 to read the reference voltage from the floating diffusion node FD. At time d′, after the transfer transistor 312₁ has been turned on for charge transfer and then off after completion, the image signal voltage is then retrieved from the photodiode PD₁ of the selected pixel block 308₁ in accordance with steps 410 and 412. It is noted that while the transfer transistor 312₁ is turned on to transfer the image signal from the selected pixel block 308₁ to the floating diffusion node FD, the transfer transistors of all other unselected pixel blocks of the pixel circuit 302 remain turned off. At time e′, the floating diffusion node FD is then reset by turning high the gate voltage RG of the reset transistor 304 and turning low V_{RG} in accordance with step 414. Steps 408-414 then are repeated to successively process the pixel block 308₂ between time f′ and g′, pixel block 308₃ between time h′ and i″, and pixel block 308₄ between time j′ and k′.

By providing a pixel circuit in which multiple pixel blocks share a common reset transistor and source follower transistor, the effective number of transistors per pixel block is reduced. To illustrate, the example illustrated in FIG. 1 has a number of three transistors for one pixel. In contrast, the example of FIG. 3 has a total number of six transistors for four pixel blocks, i.e. the effective number of transistors per pixel is 1.5. Accordingly, compared to the embodiment of FIG. 1, the embodiment of FIG. 3 has an increased pixel fill factor. While the illustrated embodiment of FIG. 3 describes a pixel circuit with four pixels blocks, a person skilled in the art will readily appreciate that more or less pixel blocks may be coupled in the pixel circuit.

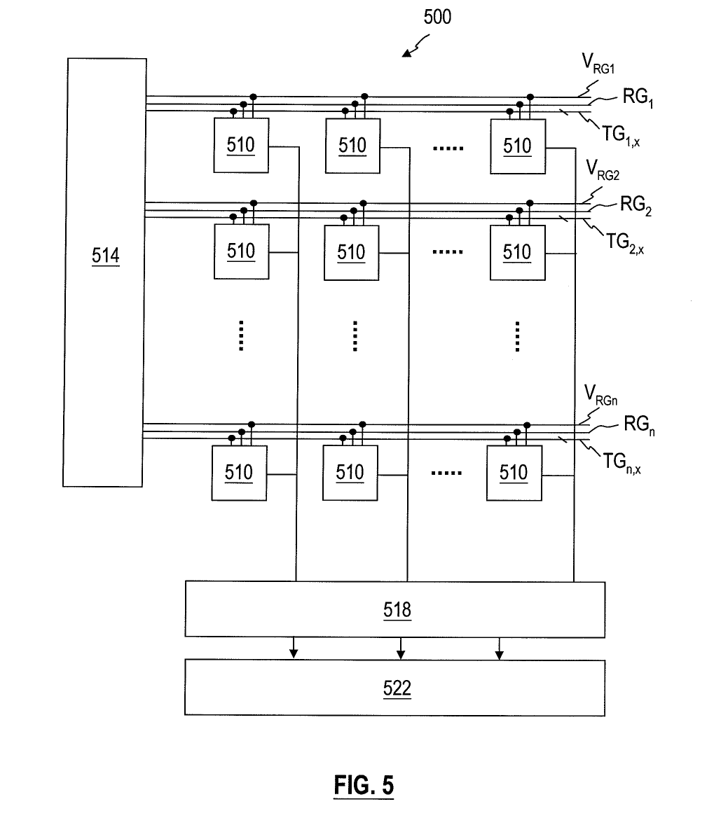

FIG. 5 is a conceptual diagram of a CMOS imager device 500 adapted to implement one or more aspects of the present invention. The CMOS imager device 500 comprises a two-dimensional array of active pixel sensors 510 that are arranged in a number of n rows and m columns. Each active pixel sensor 510 has a pixel circuit that comprises one or more photodiode, one transfer transistor associated with each photodiode, a reset transistor and a source follower transistor. Examples of suitable pixel circuitries for each active pixel sensor 510 may comprise either the pixel circuit 102 or pixel circuit 302 described previously. A row driver circuit 514 supplies a set of common control signals to each row of active pixel sensors 510. The control signals provided to each row j comprise a driving voltage V_{RGj} supplied to the drain of each reset transistor coupled in the row j, a control voltage RGⱼ provided to the gate of each reset transistor in the row j, and one or more voltage TG_{j,x} respectively provided to the gate of each transfer transistor in each active pixel sensor 510 of the row j, wherein j is the row index ranging from 1 to the total number of row n, and x is an index ranging from 1 to the total number of transfer transistors provided in each active pixel sensor 510. A column sampler and hold circuit 518 is configured to receive reference voltages and image signals respectively read out from each column of active pixel sensors 510. A programmable gain amplifier (PGA)/analog-to-digital converter (ADC) 522 then amplifies these voltage signals, and converts them into a digital form that is stored in a memory device (not shown).

As has been described above, the provided method and circuit is thus able to select each row of active pixels independently of adjacent pixel rows by coupling the drain of the reset transistor to a driving voltage signal whereas the drain of the source follower transistor is coupled to a constant voltage. As a result, power consumption and coupling noise can be reduced.

The above description illustrates various embodiments of the present invention along with examples of how aspects of the present invention may be implemented. The above examples, embodiments, instruction semantics, and drawings should not be deemed to be the only embodiments, and are presented to illustrate the flexibility and advantages of the present invention as defined by the following claims.

We claim:

1. A pixel circuit comprising:
at least one photodiode;
a first transistor coupled between the photodiode and a floating node;
a second transistor coupled between the floating diffusion node and a modifiable driving voltage; and
a third transistor having a third-transistor gate coupled to the floating diffusion node, a third-transistor source coupled to a signal output, and a third-transistor drain coupled to a constant voltage.

2. The pixel circuit of claim 1, wherein any of the first, second, and third transistors is a metal-oxide-semiconductor field-effect transistor.

3. The pixel circuit of claim 1, further comprising a plurality of photodiodes.

4. The pixel circuit of claim 3, wherein the plurality of photodiodes are commonly connected to the floating diffusion node.

5. The pixel circuit of claim 1, wherein the second transistor has a second-transistor drain coupled to the modifiable driving voltage and a second-transistor source coupled to the floating diffusion node.

6. The pixel circuit of claim 1, wherein the modifiable driving voltage is toggled between a high voltage level and a low voltage level to either select or unselect the pixel circuit.

7. An imager device comprising:
an array of active pixels arranged in rows and columns;
a row driver circuit configured to provide control signals to each row of active pixels; and
a signal output circuit configured to receive analog signals issued by each column of active pixels, wherein each active pixel in a same row has a pixel circuit that comprises:
at least one photodiode;
a first transistor coupled between the photodiode and an floating diffusion node;
a second transistor coupled between the floating diffusion node and a driving voltage signal commonly coupled to all active pixels in the row; and
a third transistor having a gate coupled to the floating diffusion node, a source coupled to a signal output, and a drain coupled to a constant voltage.

8. The imager device of claim 7, wherein any of the first, second, and third transistor is a metal-oxide-semiconductor field-effect transistor.

9. The imager device of claim 7, wherein the pixel circuit further comprises a plurality of photodiodes.

10. The imager device of claim 9, wherein the plurality of photodiodes of the same pixel circuit are commonly connected to the floating diffusion node.

11. The imager device of claim 7, wherein the second transistor has a second-transistor drain coupled to the driving voltage signal and a second-transistor source coupled to the floating diffusion node.

12. The imager device of claim 7, wherein each driving voltage signal is toggled between a high voltage level and a low voltage level to either select or unselect the corresponding row of active pixels.

13. A method for driving a pixel circuit of an imager device, the pixel circuit comprising at least one photodiode, a first transistor coupled between the photodiode and a floating diffusion node, a second transistor coupled between the floating diffusion node and a driving voltage signal, and a third transistor having a gate coupled to the floating diffusion node and a source coupled to a signal output, the method comprising:
resetting the photodiode;
exposing the photodiode to light to accumulate charges;
selecting the pixel circuit by switching the driving voltage signal from a first voltage level to a second voltage level;
retrieving a reference voltage from the selected pixel circuit; and
retrieving an image signal from the selected pixel circuit corresponding to the accumulated charges.

14. The method of claim 13, further comprising continuously applying a constant voltage to a drain of the third transistor during operation of the pixel circuit.

15. The method of claim 13, wherein the first voltage level is lower than the second voltage level.

16. The method of claim 15, wherein resetting the photodiode and the floating diffusion node further comprises:
switching the driving voltage signal from the first voltage level to the second voltage level; and
turning on the first transistor.

17. The method of claim 15, wherein retrieving the reference voltage from the selected pixel circuit further comprises:
keeping the first transistor in a turned-off state;
raising the driving voltage signal from the first voltage level to the second voltage level; and
lowering a gate voltage of the second transistor from a third voltage level to a fourth voltage level after the driving voltage signal has been raised to the second voltage level.

18. The method of claim 15, wherein retrieving the image signal from the pixel circuit corresponding to the accumulated charges comprises:
lowering a gate voltage of the second transistor from a third voltage level to a fourth voltage level; and
turning on the first transistor to transfer the accumulated charges from the photodiode to the floating diffusion node.

19. The method of claim 18, wherein retrieving the image signal from the pixel circuit corresponding to the accumulated charges further comprises:
turning off the first transistor; and
reading out the image signal corresponding to the accumulated charges received at the floating diffusion node.
